(19) United States
(12) Patent Application Publication
(10) Pub. No.: US 2026/0089968 A1
(43) Pub. Date: Mar. 26, 2026

(54) SEMICONDUCTOR MEMORY DEVICE AND MEMORY CHIP INCLUDING THE SAME

(71) Applicant: SAMSUNG ELECTRONICS CO., LTD., Suwon-si (KR)

(72) Inventors: Se Ryeun YANG, Suwon-si (KR); Jeon Il LEE, Suwon-si (KR); Young In GOH, Suwon-si (KR); Seo Ha LEE, Suwon-si (KR)

(73) Assignee: SAMSUNG ELECTRONICS CO., LTD., Suwon-si (KR)

(21) Appl. No.: 19/253,029

(22) Filed: Jun. 27, 2025

(30) Foreign Application Priority Data
Sep. 23, 2024 (KR) 10-2024-0128301

(51) Int. Cl. H10B 51/30; H10B 51/20

(52) U.S. Cl. CPC H10B 51/30; H10B 51/20

(57) ABSTRACT

A semiconductor memory device may include: gate electrodes spaced apart in a first horizontal direction, extending in a second horizontal direction, and including first sidewalls and second sidewalls opposite to the first sidewalls in the first horizontal direction; first isolation patterns on the first sidewalls and the second sidewalls, spaced apart in the second horizontal direction; at least one channel layer between adjacent first isolation patterns in the second horizontal direction, contacting at least one of the first sidewalls and at least one of the second sidewalls, the at least one channel layer including, in a following order in the first horizontal direction: a dielectric layer including a ferroelectric or antiferroelectric material; an intermediate electrode; a gate insulating layer; and a semiconductor layer; and source/drain lines extending in a vertical direction between adjacent gate electrodes in the first horizontal direction.

### CROSS-REFERENCE TO RELATED APPLICATION

This application claims priority from Korean Patent Application No. 10-2024-0128301 filed on Sep. 23, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor memory device and a memory chip including the same.

### 2. Description of the Related Art

Due to the advancement of electronic technology, the down-scaling of semiconductor devices is progressing rapidly, and higher integration is required to increase the storage capacity of semiconductor memory devices used in electronic devices. In particular, there is a need for the development of technology for 3D memory devices with a structure that can secure the reliability required by memory cells even as the number of stacked memory cells overlapping in a vertical direction on a substrate increases.

### SUMMARY

Aspects of the present disclosure provide a memory device with improved product reliability.

Aspects of the present disclosure also provide a memory chip with improved product reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more example embodiments, a semiconductor memory device my include: gate electrodes spaced apart in a first horizontal direction, extending in a second horizontal direction, and including first sidewalls and second sidewalls opposite to the first sidewalls in the first horizontal direction; first isolation patterns on the first sidewalls and the second sidewalls, spaced apart in the second horizontal direction; at least one channel layer between adjacent first isolation patterns in the second horizontal direction, contacting at least one of the first sidewalls and at least one of the second sidewalls, the at least one channel layer including, in a following order in the first horizontal direction: a dielectric layer including a ferroelectric or antiferroelectric material; an intermediate electrode; a gate insulating layer; and a semiconductor layer; and source/drain lines extending in a vertical direction between adjacent gate electrodes in the first horizontal direction.

According to one or more example embodiments, a semiconductor memory device may include: insulating layers and gate electrodes alternately stacked in a vertical direction; source/drain lines spaced apart in a second horizontal direction and extending in the vertical direction on sides of the insulating layers and the gate electrodes in a first horizontal direction; dielectric layers between the source/drain lines and the gate electrodes, the dielectric layers including a ferroelectric or antiferroelectric material; semiconductor layers between the source/drain lines and the dielectric layers; and first isolation patterns penetrating at least one of the dielectric layers and at least one of the semiconductor layers and spaced apart in the second horizontal direction.

According to one or more example embodiments, a semiconductor memory chip may include: a front-end-of-line (FEOL) structure including a semiconductor substrate and transistors on the semiconductor substrate; and a back-end-of-line (BEOL) structure on the FEOL structure, including a memory array electrically connected to the transistors, wherein the memory array includes: insulating layers and gate electrodes alternately stacked in a vertical direction; source/drain lines spaced apart in a second horizontal direction and extending in the vertical direction on sides of the insulating layers and the gate electrodes in a first horizontal direction; at least one channel layer between the source/drain lines and the gate electrodes, the at least one channel layer including: a dielectric layer including a ferroelectric or antiferroelectric material; a gate dielectric layer; and a semiconductor layer; and first isolation patterns extending in the vertical direction, penetrating at least a portion of the at least one channel layer, and disposed between adjacent source/drain lines in the second horizontal direction.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary circuit diagram for describing a semiconductor memory device according to one or more embodiments;

FIG. 2 is an exemplary perspective view for describing the semiconductor memory device according to one or more embodiments;

FIG. 3 is a cross-sectional view taken along line A-A′ of FIG. 2;

FIG. 4 is a cross-sectional view taken along line B-B′ of FIG. 2;

FIG. 5 is an exemplary plan view for describing a semiconductor memory device according to one or more embodiments;

FIG. 6 is a cross-sectional view taken along line A-A′ of FIG. 2;

FIG. 7 is an example perspective view for describing semiconductor memory devices according to one or more embodiments;

FIG. 8 is an example perspective view for describing semiconductor memory devices according to one or more embodiments;

FIG. 9 is an example perspective view for describing semiconductor memory devices according to one or more embodiments;

FIG. 10 is an exemplary plan view for describing a semiconductor memory device according to one or more embodiments;

FIG. 11 is a drawing for describing a method of manufacturing a semiconductor memory device according to one or more embodiments;

FIG. 12 is a drawing for describing a method of manufacturing a semiconductor memory device according to one or more embodiments;

FIG. 13 is a drawing for describing a method of manufacturing a semiconductor memory device according to one or more embodiments;

FIG. 14 is a drawing for describing a method of manufacturing a semiconductor memory device according to one or more embodiments;

FIG. 15 is a drawing for describing a method of manufacturing a semiconductor memory device according to one or more embodiments;

FIG. 16 is a drawing for describing a method of manufacturing a semiconductor memory device according to one or more embodiments;

FIG. 17 is a drawing for describing a method of manufacturing a semiconductor memory device according to one or more embodiments;

FIG. 18 is a drawing for describing a method of manufacturing a semiconductor memory device according to one or more embodiments;

FIG. 19 is a drawing for describing a method of manufacturing a semiconductor memory device according to one or more embodiments;

FIG. 20 is a drawing for describing a method of manufacturing a semiconductor memory device according to one or more embodiments;

FIG. 21 is a drawing for describing a method of manufacturing a semiconductor memory device according to one or more embodiments;

FIG. 22 is a drawing for describing a method of manufacturing a semiconductor memory device according to one or more embodiments;

FIG. 23 is a drawing for describing a method of manufacturing a semiconductor memory device according to one or more embodiments;

FIG. 24 is a drawing for describing a method of manufacturing a semiconductor memory device according to one or more embodiments;

FIG. 25 is a drawing for describing a method of manufacturing a semiconductor memory device according to one or more embodiments;

FIG. 26 is a drawing for describing a method of manufacturing a semiconductor memory device according to one or more embodiments;

FIG. 27 is a drawing for describing a method of manufacturing a semiconductor memory device according to one or more embodiments;

FIG. 28 is a drawing for describing a method of manufacturing a semiconductor memory device according to one or more embodiments;

FIG. 29 is a drawing for describing a method of manufacturing a semiconductor memory device according to one or more embodiments;

FIG. 30 is a drawing for describing a method of manufacturing a semiconductor memory device according to one or more embodiments;

FIG. 31 is a drawing for describing a method of manufacturing a semiconductor memory device according to one or more embodiments;

FIG. 32 is a drawing for describing a method of manufacturing a semiconductor memory device according to one or more embodiments;

FIG. 33 is a drawing for describing a method of manufacturing a semiconductor memory device according to one or more embodiments;

FIG. 34 is a drawing for describing a method of manufacturing a semiconductor memory device according to one or more embodiments; and

FIG. 35 is a drawing for describing a semiconductor memory chip according to one or more embodiments.

### DETAILED DESCRIPTION

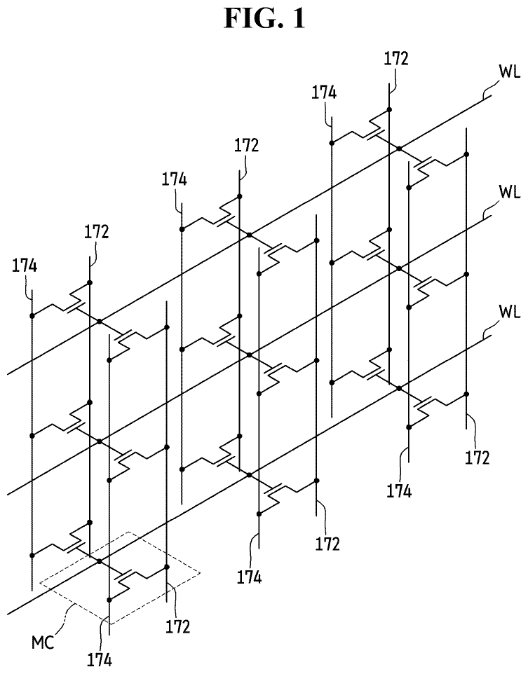

FIG. 1 is an exemplary circuit diagram for describing a semiconductor memory device according to one or more embodiments.

In the specification, spatially relative terms such as “top”, “bottom”, “upper”, “lower”, “up”, “down”, “horizontal,” “vertical” etc. are used to easily explain the positional relationship of each component when viewed from a direction depicted in the drawings. Therefore, spatially relative terms indicating the positional relationship of each component may be understood differently when viewed from a direction other than the direction depicted in the drawings.

Referring to FIG. 1, the semiconductor memory device according to one or more embodiments may include a plurality of source lines 172, a plurality of drain lines 174, a plurality of wordlines WL, and a plurality of memory cells MC.

The memory cells MC may operate as transistors. The gates of the transistors may be electrically connected to the wordlines WL, the source regions of the transistors may be electrically connected to the source lines 172, and the drain regions of the transistors may be electrically connected to the drain lines 174.

Multiple memory cells MC in the same row may share one wordline WL. Multiple memory cells MC in the same column may share one source line 172 and one drain line 174.

In the semiconductor memory device according to one or more embodiments, the memory cells MC may be configured as ferroelectric field effect transistors (FeFETs).

The semiconductor memory device according to one or more embodiments may be a volatile memory device, such as a dynamic-random access memory (DRAM). Alternatively, the semiconductor memory device according to one or more embodiments may be a non-volatile memory device, such as a flash memory.

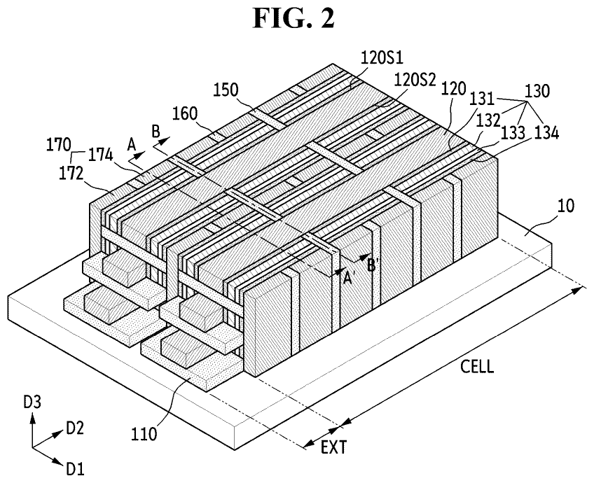

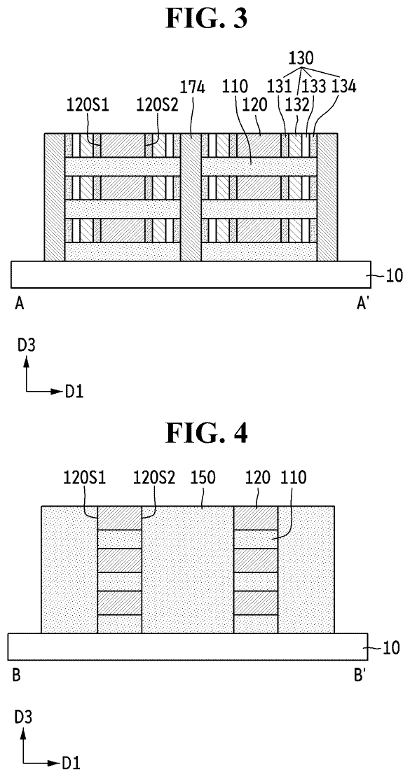

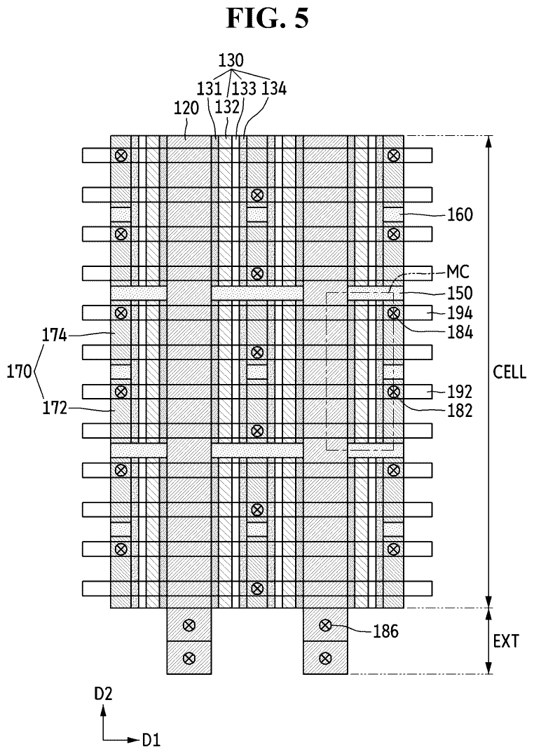

FIG. 2 is an exemplary perspective view for describing a semiconductor memory device according to one or more embodiments. FIG. 3 is a cross-sectional view taken along line A-A′ of FIG. 2. FIG. 4 is a cross-sectional view taken along line B-B′ of FIG. 2. FIG. 5 is an exemplary plan view for describing a semiconductor memory device according to one or more embodiments. As a reference, in FIGS. 2 through 4, source contacts 182, drain contacts 184, gate contacts 186, source conductive lines 192, and drain conductive lines 194 of FIG. 5 are omitted.

Referring to FIGS. 2 through 5, the semiconductor memory device according to one or more embodiments includes a substrate 10, a plurality of insulating layers 110, a plurality of gate electrodes 120, a plurality of channel layers 130, a plurality of first isolation patterns 150, and a plurality of second isolation patterns 160.

The substrate 10 may include, for example, a semiconductor substrate such as a silicon (Si) substrate, a germanium (Ge) substrate, or a silicon-germanium (SiGe) substrate. Alternatively, the substrate 10 may include a silicon-on-insulator (SOI) substrate or a germanium-on-insulator (GOI) substrate. For example, the substrate 10 may include a buried oxide (BOX) layer.

The substrate 10 may include a cell region CELL and an extension region EXT.

A plurality of memory cells MC may be formed in the cell region CELL. The memory cells MC may be arranged in the form of a three-dimensional (3D) array. The cell region CELL may include the insulating layers 110, the gate electrodes 120, the channel layers 130, the first isolation patterns 150, and the second isolation patterns 160. The extension region EXT may be disposed around the cell region CELL. In the extension region EXT, the insulating layers 110 and the gate electrodes 120 may be stacked in a stair-like fashion.

Here, a first horizontal direction D1 and a second horizontal direction D2 intersect each other and are parallel to the top surface of the substrate 10, and a vertical direction D3 intersects the first and second horizontal directions D1 and D2 and is perpendicular to the top surface of the substrate 10. The top surface and bottom surface of each element are defined with respect to the vertical direction D3.

A plurality of gate electrodes 120 may be disposed on the substrate 10. The gate electrodes 120 may be stacked on the substrate 10 to be spaced apart in the vertical direction D3. The gate electrodes 120 may be arranged in the vertical direction D3. The gate electrodes 120 may also be spaced apart in the first horizontal direction D1. The gate electrodes 120 may be arranged in the first horizontal direction D1.

The gate electrodes 120 may extend in the second horizontal direction D2. The gate electrodes 120 may include first sidewalls 120S1 and second sidewalls 120S2 that are adjacent to the first sidewalls 120S1 in the first horizontal direction D1. The gate electrodes 120 may be the wordlines WL of FIG. 1.

The gate electrodes 120 may include a conductive material. For example, the gate electrodes 120 may include at least one of a doped semiconductor material (e.g., doped Si, doped Ge, etc.), a conductive metal nitride (e.g., titanium nitride, tantalum nitride, etc.), a metal (e.g., tungsten (W), titanium (Ti), tantalum (Ta), etc.), a metal-semiconductor compound (e.g., tungsten silicide, cobalt silicide, titanium silicide, etc.), or a combination thereof, but the present disclosure is not limited thereto.

The insulating layers 110 may be disposed on the substrate 10. The insulating layers 110 may be stacked and spaced apart in the vertical direction D3. The insulating layers 110 may be disposed between adjacent gate electrodes 120 in the vertical direction D3. The insulating layers 110 and the gate electrodes 120 may be alternately stacked in the vertical direction D3 on the substrate 10. The width, in the first horizontal direction D1, of the insulating layers 110 may be greater than the width, in the first horizontal direction D1, of the gate electrodes 120.

The insulating layers 110 may include, for example, silicon oxide or silicon oxynitride, but the present disclosure is not limited thereto.

The channel layers 130 may be disposed on the first sidewalls 120S1 and second sidewalls 120S2 of the gate electrodes 120. The channel layers 130 may extend in the second horizontal direction D2. The channel layers 130 may be disposed between adjacent insulating layers 110 in the vertical direction D3.

In one or more embodiments, the channel layers 130 may include dielectric layers 131, intermediate electrodes 132, gate insulating layers 133, and semiconductor layers 134. The dielectric layers 131, the intermediate electrodes 132, the gate insulating layers 133, and the semiconductor layers 134 may be sequentially disposed on the first sidewalls 120S1 and second sidewalls 120S2 of the gate electrodes 120.

The dielectric layers 131 may be disposed on the first sidewalls 120S1 and second sidewalls 120S2 of the gate electrodes 120. The dielectric layers 131 may be in contact with the gate electrodes 120. The dielectric layers 131 may include ferroelectrics or antiferroelectrics.

In one or more embodiments, the dielectric layers 131 may include ferroelectrics. Ferroelectrics are materials that have spontaneous polarization, where the direction of polarization can be changed by an external electric field. For example, the dielectric layers 131 may include at least one of hafnium oxide, zirconium oxide, yttrium (Y)-doped zirconium oxide, Y-doped hafnium oxide, magnesium (Mg)-doped zirconium oxide, Mg-doped hafnium oxide, Si-doped hafnium oxide, Si-doped zirconium oxide, barium (Ba)-doped titanium oxide, or a combination thereof.

In one or more embodiments, the dielectric layers 131 may include antiferroelectrics. Antiferroelectrics are materials that do not have spontaneous polarization in the absence of an external electric field but exhibit similar polarization properties to ferroelectrics when an external electric field is applied. For example, the dielectric layers 131 may include PbZrO₃, but the present disclosure is not limited thereto.

The intermediate electrodes 132 may be disposed on the dielectric layers 131. The intermediate electrodes 132 may be disposed between the dielectric layers 131 and the semiconductor layers 134.

The intermediate electrodes 132 may include a conductive material. For example, the intermediate electrodes 132 may include at least one of a doped semiconductor material (e.g., doped Si, doped Ge, etc.), a conductive metal nitride (e.g., titanium nitride, tantalum nitride, etc.), a metal (e.g., W, Ti, Ta, etc.), a metal-semiconductor compound (e.g., tungsten silicide, cobalt silicide, titanium silicide, etc.), or a combination thereof, but the present disclosure is not limited thereto. The intermediate electrodes 132 may include the same material as, or different materials from, the gate electrodes 120.

The gate insulating layers 133 may be disposed on the intermediate electrodes 132. The gate insulating layers 133 may be disposed between the intermediate electrodes 132 and the semiconductor layers 134.

The gate insulating layers 133 may include, for example, a single layer selected from a high-k dielectric film, a silicon oxide film, a silicon nitride film, or a silicon oxynitride film, or a combination thereof. As an example, the high-k dielectric film may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate, but the present disclosure is not limited thereto.

The semiconductor layers 134 may be disposed on the gate insulating layers 133. The semiconductor layers 134 may be in contact with the source/drain lines 170.

The semiconductor layers 134 may include, for example, undoped polysilicon, doped polysilicon, a compound semiconductor material, an oxide semiconductor material, a two-dimensional (2D) semiconductor material, or a combination thereof. The compound semiconductor material may be selected from a Group IV-IV compound semiconductor, a Group III-V compound semiconductor, a Group II-VI compound semiconductor, or a Group IV-VI compound semiconductor. The Group IV-IV compound semiconductor may be selected from SiGe, SiC, SiGeC, GeSn, SiSn, or SiGeSn. The Group III-V compound semiconductor may consist of at least one Group III element, such as In, Ga, or Al, and at least one Group V element, such as As, P, or Sb. The III-V compound semiconductor may include a binary, ternary, or quaternary compound containing two, three, or four elements selected from Groups III and V. The binary compound may be selected from, but is not limited to, InP, GaAs, GaP, InAs, InSb, or GaSb, and the ternary compound may be selected from, but is not limited to, InGaP, InGaAs, AlInAs, InGaSb, GaAsSb, or GaAsP. The Group II-VI compound semiconductor may include a binary, ternary, or quaternary compound containing two, three, or four elements selected from Groups II and VI. The Group II-VI compound semiconductor may be selected from, but is not limited to, CdSe, ZnTe, CdS, ZnS, ZnSe, or HgCdTe. The IV-VI compound semiconductor may include, but is not limited to, PbS.

The oxide semiconductor material may be selected from, but is not limited to, InGaZnO (IGZO), Sn-IGZO, InWO (IWO), InZnO (IZO), ZnSnO (ZTO), ZnO, Y-doped zinc oxide (YZO), InGaSiO (IGSO), InO, SnO, TiO, ZnON, MgZnO, ZrInZnO, HfInZnO, SnInZnO, AlSnInZnO, SiInZnO, AlZnSnO, GaZnSnO, or ZrZnSnO. The 2D semiconductor material may be a transition metal dichalcogenide or bipolar semiconductor material that uses both electrons and holes as charge carriers. For example, the 2D semiconductor material may be selected from, but is not limited to, MoS₂, MoSe₂, WS₂, NbS₂, TaS₂, ZrS₂, HfS₂, TcS₂, ReS₂, CuS₂, GaS₂, InS₂, SnS₂, GeS₂, PbS₂, WSe₂, NbSe₂, TaSe₂, ZrSe₂, HfSe₂, TcSe₂, ReSe₂, CuSe₂, GaSe₂, InSe₂, SnSe₂, GeSe₂, PbSe₂, MoTe₂, WTe₂, NbTe₂, TaTe₂, ZrTe₂, HfTe₂, TcTe₂, ReTe₂, CuTe₂, GaTe₂, InTe₂, SnTe₂, GeTe₂, or PbTe₂.

A plurality of source/drain lines 170 may be disposed on the substrate 10. The source/drain lines 170 may be spaced apart in the first horizontal direction D1. The insulating layers 110 and the gate electrodes 120 may be alternately stacked in the vertical direction D3 between adjacent source/drain lines 170 in the first horizontal direction D1. The channel layers 130 may be disposed between the source/drain lines 170 and the gate electrodes 120. In other words, the source/drain lines 170 may be spaced apart in the second horizontal direction D2 on both sides, in the first horizontal direction D1, of the gate electrodes 120 and the insulating layers 110.

The source/drain lines 170 may extend in the vertical direction D3.

The source/drain lines 170 may include source lines 172 and drain lines 174, which are spaced apart from the source lines 172 in the second horizontal direction D2. Second isolation patterns 160 may be disposed between the source lines 172 and the drain lines 174.

The source/drain lines 170 may include a conductive material. For example, the source/drain lines 170 may include at least one of a doped semiconductor material (e.g., doped silicon, doped germanium, etc.), a conductive metal nitride (e.g., titanium nitride, tantalum nitride, etc.), a metal (e.g., W, Ti, Ta, etc.), a metal-semiconductor compound (e.g., tungsten silicide, cobalt silicide, titanium silicide, etc.), or a combination thereof, but the present disclosure is not limited thereto.

A plurality of first isolation patterns 150 may be spaced apart in the second horizontal direction D2 on the first sidewalls 120S1 and second sidewalls 120S2 of the gate electrodes 120. The first isolation patterns 150 may be arranged in the second horizontal direction D2 on the first sidewalls 120S1 and second sidewalls 120S2 of the gate electrodes 120. The first isolation patterns 150 may be disposed between the adjacent gate electrodes 120 in the first horizontal direction D1. Between each pair of adjacent gate electrodes 120 in the first horizontal direction D1, the first isolation patterns 150 may be spaced apart in the second horizontal direction D2.

The first isolation patterns 150 may extend in the vertical direction D3. The first isolation patterns 150 may be disposed between the adjacent source/drain lines 170 in the second horizontal direction D2. The first isolation patterns 150 may penetrate at least portions of the channel layers 130. The first isolation patterns 150 may penetrate at least one of the dielectric layers 131 or the semiconductor layers 134.

In one or more embodiments, the first isolation patterns 150 may penetrate the channel layers 130. The first isolation patterns 150 may be disposed between adjacent channel layers 130 in the second horizontal direction D2. The channel layers 130 may be disposed between adjacent first isolation patterns 150 in the second horizontal direction D2.

In one or more embodiments, the first isolation patterns 150 may penetrate the semiconductor layers 134 but may not penetrate the dielectric layers 131. Alternatively, in one or more embodiments, the first isolation patterns 150 may penetrate the dielectric layers 131 but may not penetrate the semiconductor layers 134.

The first isolation patterns 150 may include an insulating material.

A plurality of second isolation patterns 160 may be disposed on the substrate 10. The second isolation patterns 160 may be disposed between the adjacent channel layers 130 in the second horizontal direction D2. The second isolation patterns 160 may be disposed between the adjacent first isolation patterns 150 in the second horizontal direction D2. One second isolation pattern 160 may be disposed between two adjacent first isolation patterns 150 in the second horizontal direction D2.

The second isolation patterns 160 may extend in the vertical direction D3. The second isolation patterns 160 may be disposed between the source lines 172 and the drain lines 174. The source/drain lines 170 may be separated into the source lines 172 and the drain lines 174 by the second isolation patterns 160.

The second isolation patterns 160 may include an insulating material.

In one or more embodiments, the first isolation patterns 150 may be arranged in (shaped as) straight lines along the first horizontal direction D1. The second isolation patterns 160 may be arranged in (shaped as) straight lines along the first horizontal direction D1. The source lines 172 and the drain lines 174 may be arranged in (shaped as) straight lines along the first horizontal direction D1.

The source contacts 182 may be disposed on the source lines 172. The source contacts 182 may electrically connect the source lines 172 to the source conductive lines 192. The drain contacts 184 may be disposed on the drain lines 174. The drain contacts 184 may electrically connect the drain lines 174 to the drain conductive lines 194. For example, the source contacts 182 and the drain contacts 184 may be formed in the cell region CELL.

The source conductive lines 192 and the drain conductive lines 194 may extend, for example, in the first horizontal direction D1. The source contacts 182, the source conductive lines 192, the drain contacts 184, and the drain conductive lines 194 may include a conductive material.

The gate contacts 186 may be disposed on the gate electrodes 120. The gate contacts 186 may electrically connect the gate electrodes 120 to gate conductive lines. For example, the gate contacts 186 may be formed in the extension region EXT.

The semiconductor memory device according to one or more embodiments may include the gate electrodes 120, the dielectric layers 131, the intermediate electrodes 132, the gate insulating layers 133, and the semiconductor layers 134. Therefore, by adjusting the ratio of the capacitance of the dielectric layers 131 between the gate electrodes 120 and the intermediate electrodes 132 and the capacitance of the gate insulating layers 133 between the intermediate electrodes 132 and the semiconductor layers 134, the voltage applied to the gate insulating layers 133 can be lowered, thereby improving the durability of the gate insulating layers 133.

In the semiconductor memory device according to one or more embodiments, the semiconductor layers 134 may be separated for the respective memory cells MC by the insulating layers 110 and the second isolation patterns 160. The second isolation patterns 160 may be disposed between adjacent memory cells MC in the second horizontal direction D2, and the semiconductor layers 134 of the adjacent memory cells MC in the second horizontal direction D2 may be separated by the second isolation patterns 160. The insulating layers 110 may be disposed between adjacent memory cells MC in the vertical direction D3, and the semiconductor layers 134 of the adjacent memory cells MC in the vertical direction D3 may be separated by the insulating layers 110. That is, the adjacent memory cells MC in the second horizontal direction D2 or the vertical direction D3 do not share the semiconductor layers 134. Therefore, during a read operation on the memory cells MC, interference between the semiconductor layers 134 of the memory cells MC where the read operation is being performed and the semiconductor layers 134 of the neighboring memory cells MC in the vertical direction D3 or the second horizontal direction D2 may be reduced.

Furthermore, the dielectric layers 131 may be separated for the respective memory cells MC by the insulating layers 110 and the second isolation patterns 160. The second isolation patterns 160 may be disposed between the adjacent memory cells MC in the second horizontal direction D2, and the dielectric layers 131 of the adjacent memory cells MC in the second horizontal direction D2 may be separated by the second isolation patterns 160. The insulating layers 110 may be disposed between the adjacent memory cells MC in the vertical direction D3, and the dielectric layers 131 of the adjacent memory cells MC in the vertical direction D3 may be separated by the insulating layers 110. That is, the adjacent memory cells MC in the second horizontal direction D2 or the vertical direction D3 do not share the dielectric layers 131. Therefore, during a write operation on the memory cells MC, interference between the dielectric layers 131 of memory cells MC where the write operation is being performed and the dielectric layers 131 of the neighboring memory cells MC in the vertical direction D3 or the second horizontal direction D2 may be reduced.

Accordingly, the operational characteristics and reliability of the semiconductor memory device according to one or more embodiments can be improved.

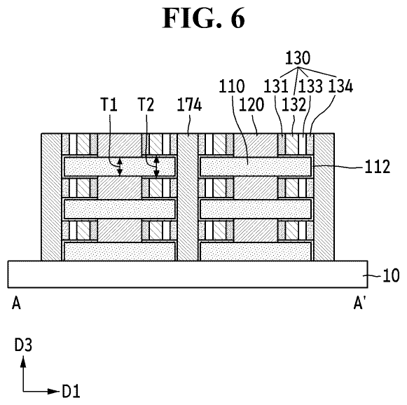

FIG. 6 is a cross-sectional view taken along line A-A′ of FIG. 2. For convenience, content that overlaps with what has been described above with reference to FIGS. 1 through 5 will be briefly explained or omitted.

Referring to FIG. 6, the semiconductor memory device according to one or more embodiments may further include insulating caps 112. The insulating caps 112 may be disposed between insulating layers 110 and source/drain lines 170, and between the insulating layers 110 and channel layers 130.

The insulating caps 112 may include the same material as second isolation patterns 160. The insulating caps 112 may include the same material as the insulating layers 110. The boundaries between the insulating layers 110 and the insulating caps 112 may not be distinguishable. That is, the insulating caps 112 may be parts of the insulating layers 110. For example, a thickness T1, in a vertical direction D3, of the insulating layers 110 between adjacent gate electrodes 120 in the vertical direction D3 may be smaller than a thickness T2, in the vertical direction D3, of the insulating layers 110 between adjacent channel layers 130 in the vertical direction D3. In other words, the thickness, in the vertical direction D3, of the gate electrodes 120 may be greater than the thickness, in the vertical direction D3, of the channel layers 130.

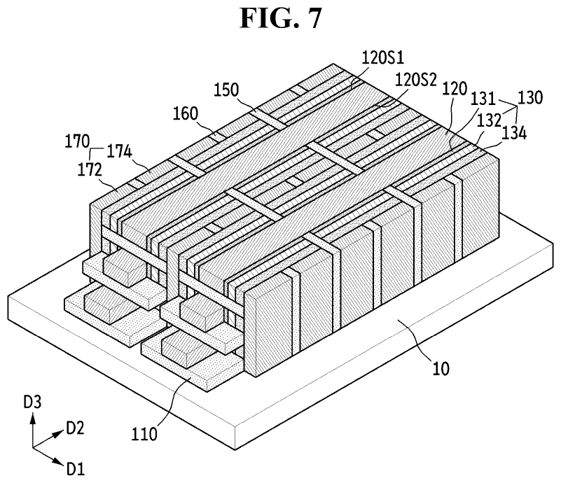

FIGS. 7 through 9 are exemplary perspective views for describing semiconductor memory devices according to one or more embodiments. For convenience, content that overlaps with what has been described above with reference to FIGS. 1 through 6 will be briefly explained or omitted.

Referring to FIG. 7, in the semiconductor memory device according to one or more embodiments, channel layers 130 may include dielectric layers 131, which include a ferroelectric or antiferroelectric material, intermediate electrodes 132, and semiconductor layers 134. The dielectric layers 131, the intermediate electrodes 132, and the semiconductor layers 134 may be sequentially disposed on first sidewalls 120S1 and second sidewalls 120S2 of gate electrodes 120.

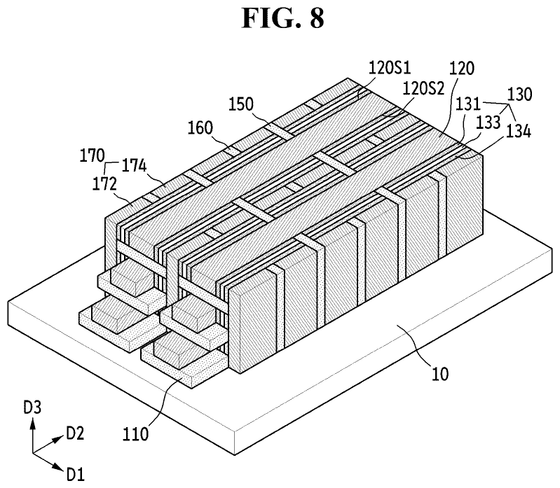

Referring to FIG. 8, in the semiconductor memory device according to one or more embodiments, channel layers 130 may include dielectric layers 131, which include a ferroelectric or antiferroelectric material, gate insulating layers 133, and semiconductor layers 134. The dielectric layers 131, the gate insulating layers 133, and the semiconductor layers 134 may be sequentially disposed on first sidewalls 120S1 and second sidewalls 120S2 of gate electrodes 120. The gate insulating layers 133 may be disposed between the dielectric layers 131 and the semiconductor layers 134.

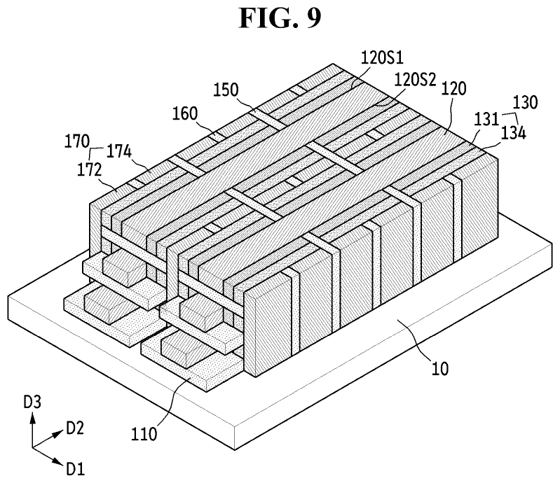

Referring to FIG. 9, in the semiconductor memory device according to one or more embodiments, channel layers 130 may include dielectric layers 131, which include a ferroelectric or antiferroelectric material, and semiconductor layers 134. The dielectric layers 131 and the semiconductor layers 134 may be sequentially disposed on first sidewalls 120S1 and second sidewalls 120S2 of gate electrodes 120.

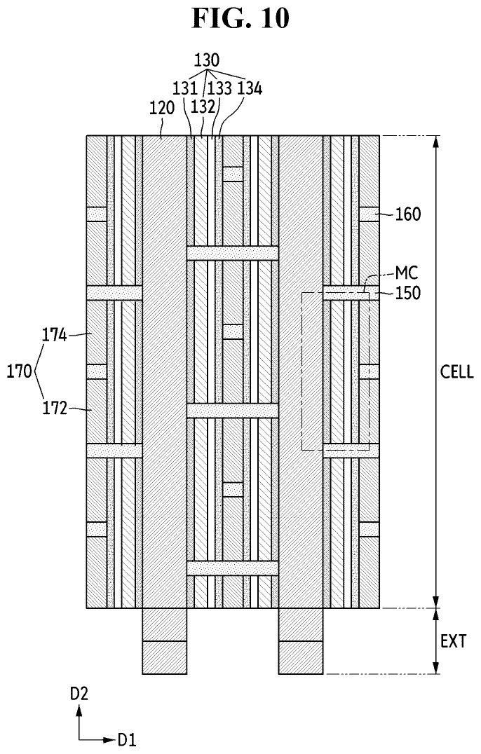

FIG. 10 is an exemplary plan view for describing a semiconductor memory device according to one or more embodiments. For convenience, content that overlaps with what has been described above with reference to FIGS. 1 through 9 will be briefly explained or omitted.

Referring to FIG. 10, in the semiconductor memory device according to one or more embodiments, first isolation patterns 150 may be arranged in a zigzag fashion along a first horizontal direction D1. Second isolation patterns 160 may be arranged in a zigzag fashion along the first horizontal direction D1. The first isolation patterns 150 and the second isolation patterns 160 may not overlap with each other in the first horizontal direction D1. Source lines 172 and drain lines 174 may be arranged in a zigzag fashion along the first horizontal direction D1. By arranged in a zigzag pattern, these components may be offset in the second horizontal direction D2 from adjacent components in the first direction D1.

The channel layers 130 may be the same as described with reference to FIGS. 1 through 9. For example, the channel layers 130 may include dielectric layers 131, intermediate electrodes 132, gate insulating layers 133, and semiconductor layers 134, as illustrated in FIG. 2. As another example, the channel layers 130 may include dielectric layers 131, intermediate electrodes 132, and semiconductor layers 134, as illustrated in FIG. 7. As yet another example, the channel layers 130 may include dielectric layers 131, gate insulating layers 133, and semiconductor layers 134, as illustrated in FIG. 8. As still another example, the channel layers 130 may include dielectric layers 131 and semiconductor layers 134, as illustrated in FIG. 9.

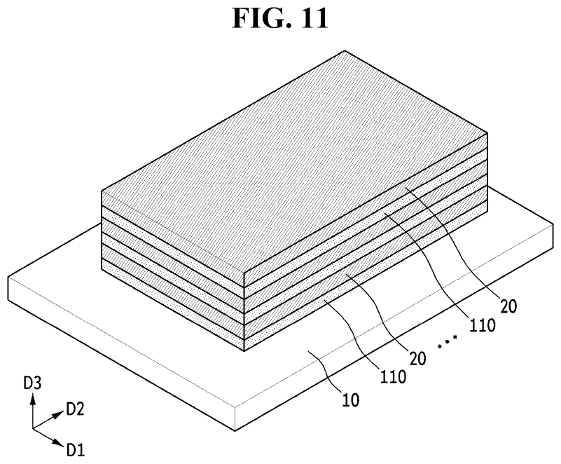

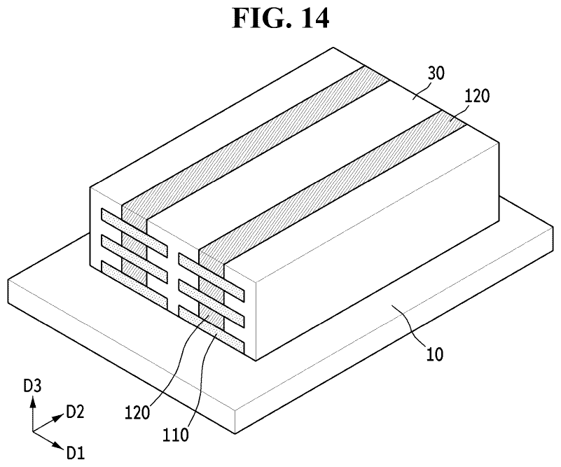

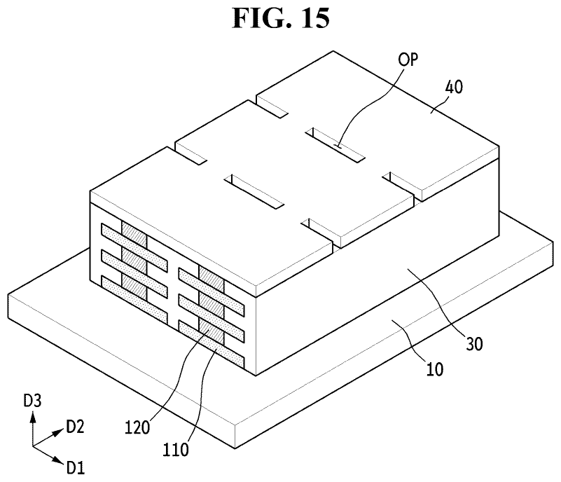

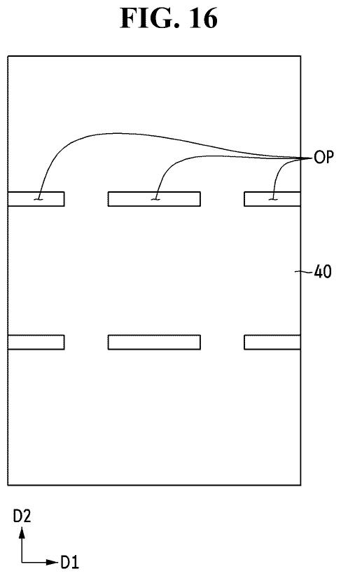

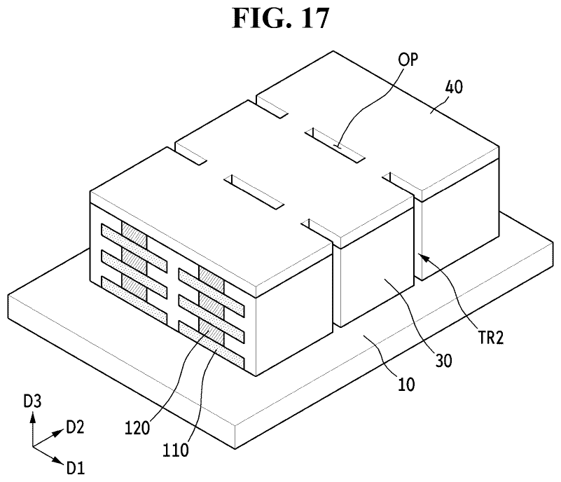

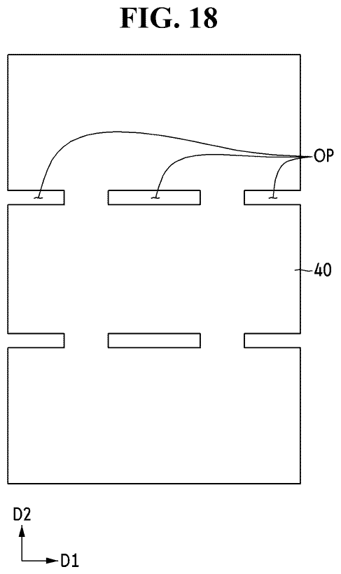

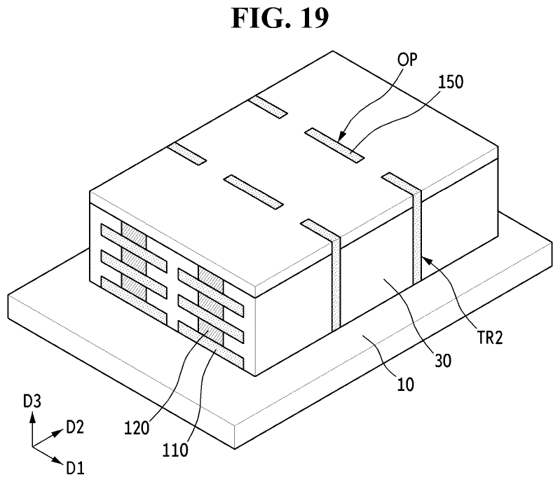

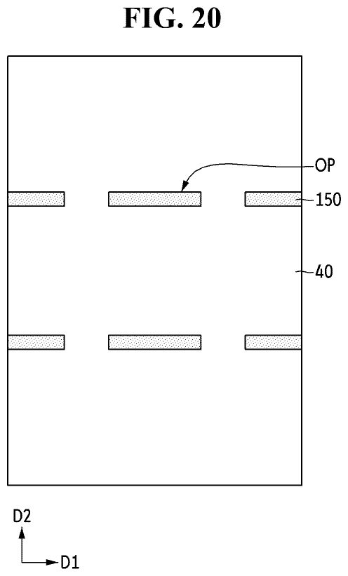

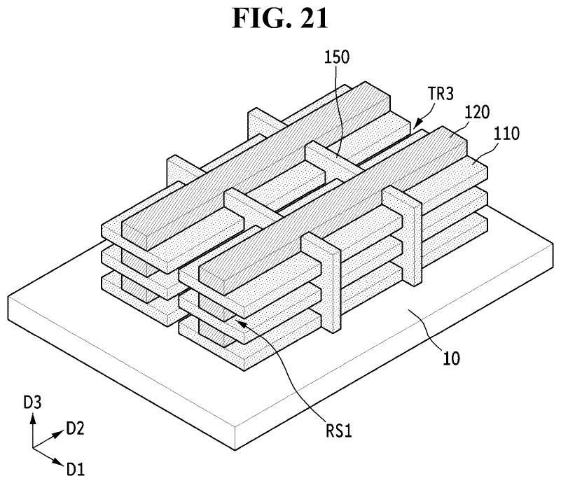

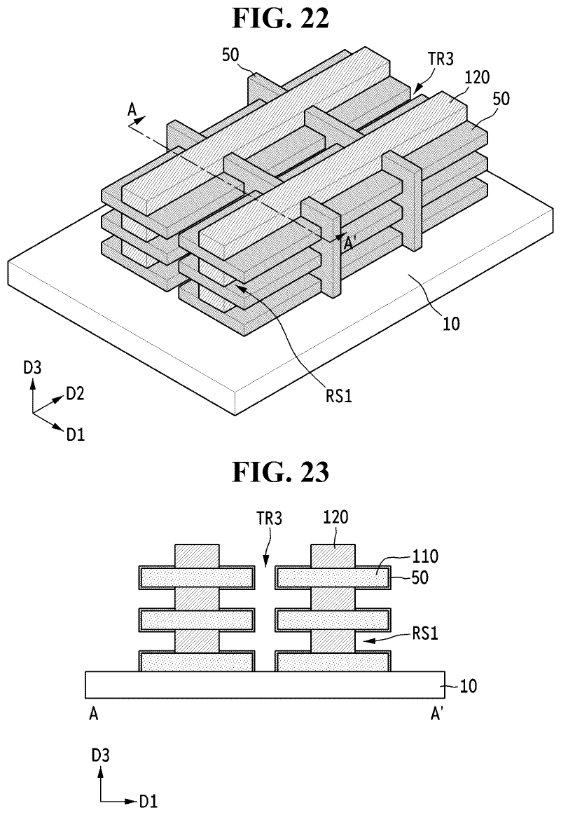

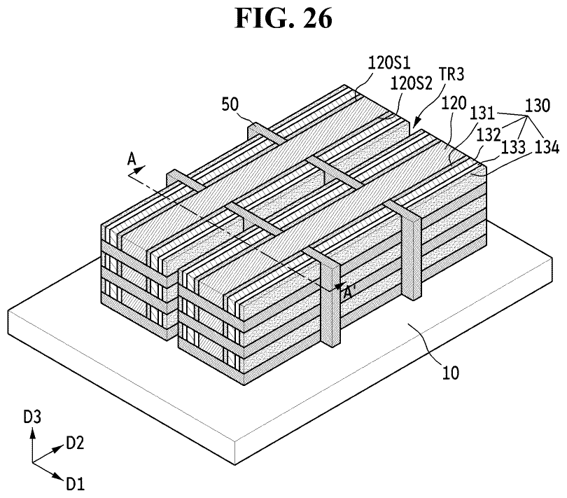

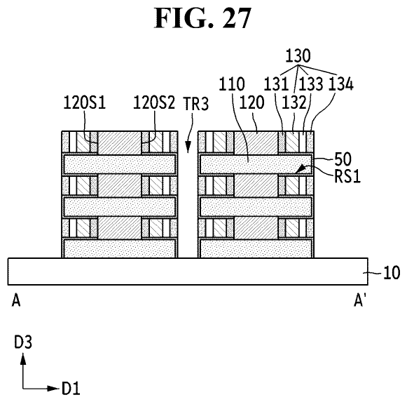

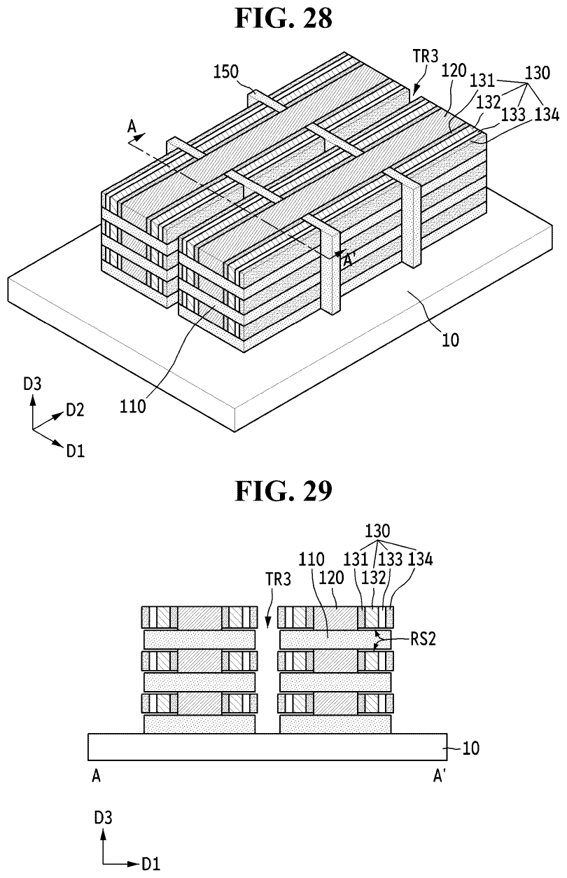

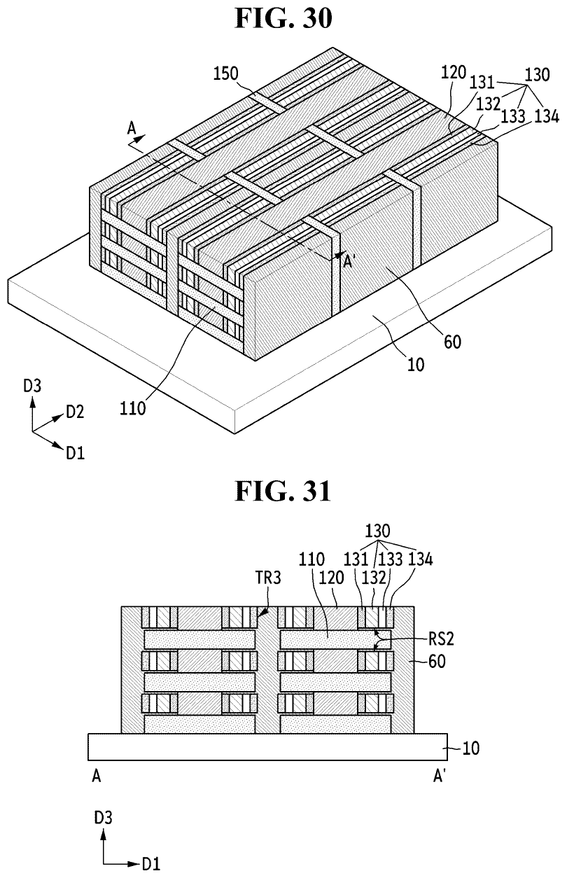

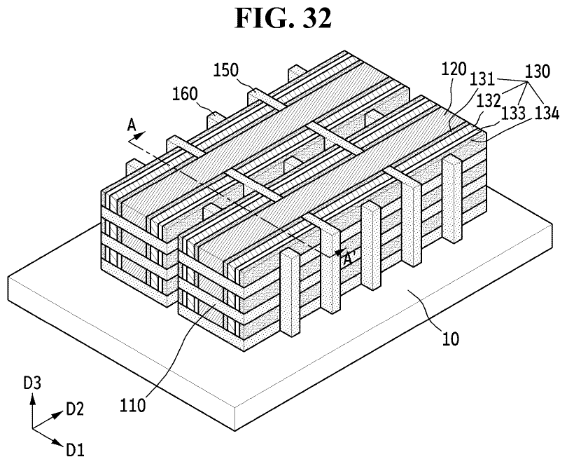

FIGS. 11 through 34 are diagrams for describing a method of manufacturing a semiconductor memory device according to one or more embodiments. For convenience, content that overlaps with what has been described above with reference to FIGS. 1 through 10 will be briefly explained or omitted. Specifically, FIG. 16 is a plan view of the structure illustrated in FIG. 15, FIG. 18 is a plan view of the structure illustrated in FIG. 17, FIG. 20 is a plan view of the structure illustrated in FIG. 19, FIG. 23 is a cross-sectional view taken along line A-A′ of FIG. 22, FIG. 27 is a cross-sectional view taken along line A-A′ of FIG. 26, FIG. 29 is a cross-sectional view taken along line A-A′ of FIG. 28, FIG. 31 is a cross-sectional view taken along line A-A′ of FIG. 30, and FIG. 33 is a cross-sectional view taken along line A-A′ of FIG. 32.

Referring to FIG. 11, a plurality of insulating layers 110 and a plurality of preliminary gate electrodes 20 may be alternately stacked in a vertical direction D3 on a substrate 10.

The insulating layers 110 may include, for example, silicon oxide, but the present disclosure is not limited thereto.

The preliminary gate electrodes 20 may include a conductive material. For example, the preliminary gate electrodes 20 may include at least one of a doped semiconductor material (e.g., doped silicon, doped germanium, etc.), a conductive metal nitride (e.g., titanium nitride, tantalum nitride, etc.), a metal (e.g., W, Ti, Ta, etc.), a metal-semiconductor compound (e.g., tungsten silicide, cobalt silicide, titanium silicide, etc.), or a combination thereof, but the present disclosure is not limited thereto.

Referring to FIG. 12, a first trench TR1, which exposes the substrate 10, may be formed by patterning the insulating layers 110 and the preliminary gate electrodes 20. The first trench TR1 may have a line shape extending along a second horizontal direction D2 and may be spaced apart in a first horizontal direction D1.

The first trench TR1 may penetrate the insulating layers 110 and the preliminary gate electrodes 20. The first trench TR1 may extend in the vertical direction D3. The sidewalls of the preliminary gate electrodes 20 and the sidewalls of the insulating layers 110 may be exposed by the first trench TR1.

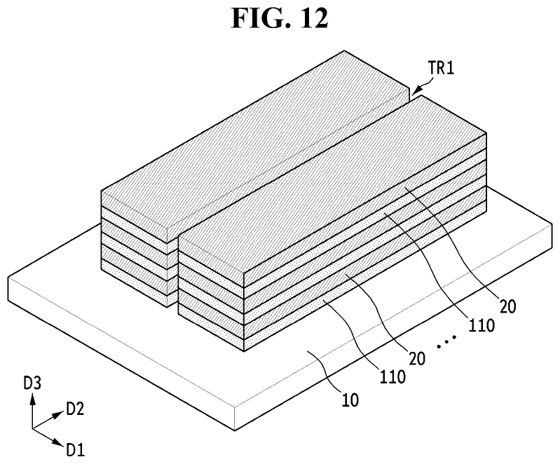

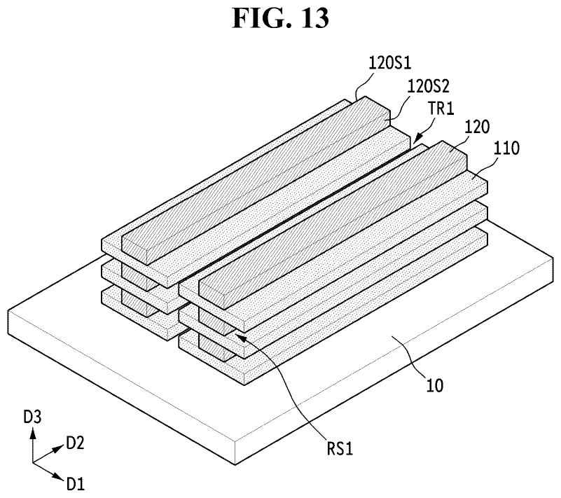

Referring to FIG. 13, portions of the preliminary gate electrodes 20 exposed by the first trench TR1 of FIG. 12 may be selectively removed, thereby forming gate electrodes 120. The gate electrodes 120 may include first sidewalls 120S1 and second sidewalls 120S2, which are opposite to the first sidewalls 120S1 in the first horizontal direction D1. Also, first recess regions RS1 may be formed between adjacent insulating layers 110 in the vertical direction D3. The first recess regions RS1 may extend along the second horizontal direction D2.

Forming the first recess regions RS1 may involve etching portions of the preliminary gate electrodes 20 by performing an etching process with etch selectivity relative to the substrate 10 and the insulating layers 110.

Referring to FIG. 14, a sacrificial film 30, which fills the first recess regions RS1 of FIG. 13 and the first trench TR1 (in FIG. 13), may be formed. The sacrificial film 30 may include, for example, a spin-on-hardmask (SOH), but the present disclosure is not limited thereto.

Referring to FIGS. 15 and 16, a mask pattern 40 may be formed on the sacrificial film 30.

The mask pattern 40 may include a plurality of openings OP. The openings OP may overlap with at least portions of the insulating layers 110 in the vertical direction D3. The openings OP may not overlap with the gate electrodes 120 in the vertical direction D3.

The mask pattern 40 may be formed of a material that can be easily removed through an ashing or stripping process. For example, the mask pattern 40 may be formed of photoresist or a carbon-rich material such as SOH.

Referring to FIGS. 17 and 18, by using the mask pattern 40 as an etch mask, portions of the sacrificial film 30 exposed through the openings OP and portions of the insulating layers 110 below the exposed portions of the sacrificial film 30 may be etched, thereby forming second trenches TR2. The second trenches TR2 may be formed at locations corresponding to the openings OP. The second trenches TR2 may expose the substrate 10.

Referring to FIGS. 19 and 20, first isolation patterns 150, which fill the second trenches TR2 and the openings OP, may be formed.

Referring to FIG. 21, the mask pattern 40 of FIGS. 19 and 20 may be removed. The first isolation patterns 150, which fill the openings OP of the mask pattern 40, may also be removed.

The sacrificial film 30 of FIGS. 19 and 20 may be removed. As a result, the first recess regions RS1 may be reformed between the adjacent insulating layers 110 in the vertical direction D3. In addition, third trenches TR3, which are spaced apart in the second horizontal direction D2 by the first isolation patterns 150, may be formed.

Referring to FIGS. 22 and 23, a self-assembled monolayer (SAM) 50 may be formed on the insulating layers 110 and the first isolation patterns 150. The SAM 50 may be selectively formed on insulating materials. The SAM 50 may not be formed on the gate electrodes 120.

In one or more embodiments, the SAM 50 may be formed on the outer surfaces of the insulating layers 110 and the outer surfaces of the first isolation patterns 150. The SAM 50 may extend along the outer surfaces of the insulating layers 110 and the outer surfaces of the first isolation patterns 150. The SAM 50 may be formed on the top surfaces, bottom surfaces, and side surfaces of the insulating layers 110. In one or more embodiments, the thickness of the SAM 50 may be smaller on the top surfaces and bottom surfaces of the insulating layers 110 than on the side surfaces of the insulating layers 110.

Alternatively, in one or more embodiments, the SAM 50 may be formed on the side surfaces of the insulating layers 110 but may not be formed on the top surfaces and bottom surfaces of the insulating layers 110. Yet alternatively, the SAM 50 may be formed on the side surfaces of the first isolation patterns 150 but may not be formed on the top surfaces and bottom surfaces of the first isolation patterns 150.

In one or more embodiments, the SAM 50 may also be formed on the top surface of the substrate 10 due to a silicon oxide film formed on the top surface of the substrate 10.

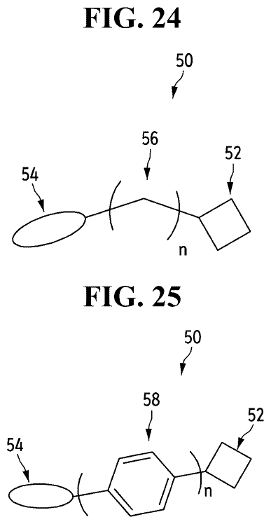

Referring to FIGS. 24 and 25, the SAM 50 may include a head group 52, a terminal group 54, and a spacer 56 or 58.

The head group 52 is one end of the SAM 50. The head group 52 is configured to be bonded to dielectric layers. The head group 52 is bonded to the insulating layers 110 of FIG. 21 and the first isolation patterns 150 of FIG. 21.

For example, the head group 52 may be bonded to an oxide material such as silicon oxide or silicon oxynitride. In one or more embodiments, the head group 52 of the SAM 50 may be trichlorosilane (—SiCl₃), carboxyl acid (—COOH), SiX₃ (X═H, OCH₂CH₃), or another suitable material.

The terminal group 54 is the opposite end of the SAM 50. The terminal group 54 is not bonded to the gate electrodes 120. The terminal group 54 is not bonded to a metal, a conductive material, or the material for forming the gate electrodes 120 (e.g., a doped semiconductor material, etc.). In one or more embodiments, the terminal group 54 reacts with a hydroxyl (—OH) group in the oxide of a dielectric layer. In one or more embodiments, the terminal group 54 may be —CH₃, —CF₃, ethylene, acetylene, or another suitable material.

The spacer 56 or 58 is connected to the head group 52 and may account for most of the volume of the SAM 50. The spacer 56 or 58 is a hydrocarbon chain. The spacer 56 or 58 may serve as a physical barrier between channel layers 130 and the insulating layers 110, as well as between the channel layers 130 and the first isolation patterns 150 when the channel layers 130 are subsequently formed.

Referring to FIG. 24, the spacer 56 is a straight or branched alkyl chain with a length of n. In one or more embodiments, the length n is between about 8 and about 20.

Referring to FIG. 25, the spacer 58 is an aromatic ring chain with a length of n. In one or more embodiments, the length n is between about 1 and about 4.

In one or more embodiments, the spacer 56 or 58 may be a combination of a straight alkyl chain, a branched alkyl chain, and an aromatic ring. The combination of the lack of reactivity of the terminal group 54 and the physical barrier formed by the spacer 56 or 58 prevents the channel layers 130 from being formed on the insulating layers 110 and the first isolation patterns 150.

Referring to FIGS. 26 and 27, channel layers 130 that fill the first recess regions RS1 may be formed on the SAM 50.

Dielectric layers 131 may be formed on the first sidewalls 120S1 and second sidewalls 120S2 of the gate electrodes 120. Intermediate electrodes 132 may be formed on the dielectric layers 131. Semiconductor layers 134 may be formed on the intermediate electrodes 132.

In one or more embodiments, gate insulating layers 133 may further be formed between the intermediate electrodes 132 and the semiconductor layers 134. For example, after forming the gate insulating layers 133 on the intermediate electrodes 132, the semiconductor layers 134 may be formed on the gate insulating layers 133. As another example, the gate insulating layers 133 may be formed during the formation of the semiconductor layers 134 on the intermediate electrodes 132.

Referring to FIGS. 28 and 29, the SAM 50 of FIGS. 26 and 27 may be removed, and the third trenches TR3 may be reformed. Second recess regions RS2 may be formed between the channel layers 130 and the insulating layers 110 adjacent to the channel layers 130 in the vertical direction D3. The top surfaces and bottom surfaces of the channel layers 130 may be spaced apart from the insulating layers 110.

Referring to FIGS. 30 and 31, a preliminary isolation film 60, which fills the third trenches TR3 and the second recess regions RS2, may be formed. The preliminary isolation film 60 may include an insulating material.

Referring to FIGS. 32 and 33, second isolation patterns 160 may be formed by patterning the preliminary isolation film 60 of FIGS. 30 and 31. The second isolation patterns 160 may be formed between adjacent first isolation patterns 150 in the second horizontal direction D2 and between adjacent channel layers 130 in the first horizontal direction D1.

Additionally, insulating caps 112, which fill the second recess regions RS2 between the channel layers 130 and the insulating layers 110 in the vertical direction D3, may be formed. The insulating caps 112 may be formed between the channel layers 130 and the insulating layers 110. The insulating caps 112 may fill the spaces between the channel layers 130 and the insulating layers 110.

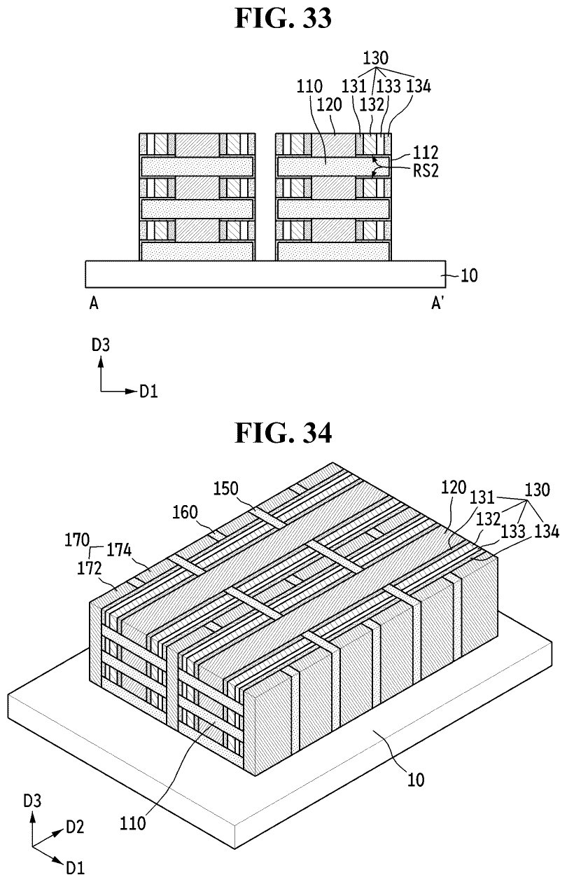

Referring to FIG. 34, source/drain lines 170, which fill the spaces between the first isolation patterns 150 and the second isolation patterns 160 in the second horizontal direction D2, may be formed. Source lines 172, which fill the spaces between the first isolation patterns 150 and the second isolation patterns 160 adjacent to the first isolation patterns 150 in the second horizontal direction D2, and drain lines 174, which fill the spaces between the second isolation patterns 160 and the first isolation patterns 150 adjacent to the second isolation patterns 160 in the second horizontal direction D2, may be formed.

Thereafter, referring to FIGS. 2 through 5, the insulating layers 110 and the gate electrodes 120 of the extension region EXT may be patterned in a stair-like fashion.

Source contacts 182 may be formed on the source lines 172. Source conductive lines 192 may be formed on the source contacts 182. Drain contacts 184 may be formed on the drain lines 174. Drain conductive lines 194 may be formed on the drain contacts 184. Gate contacts 186 may be formed on the gate electrodes 120. Gate conductive lines may be formed on the gate contacts 186.

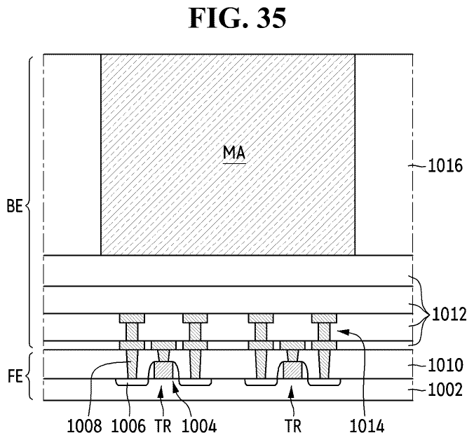

FIG. 35 is a diagram for describing a semiconductor memory chip according to one or more embodiments.

Referring to FIG. 35, the semiconductor chip according to one or more embodiments may include a front-end-of-line (FEOL) structure FE and a back-end-of-line (BEOL) structure BE.

The FEOL structure FE may include a semiconductor substrate 1002, a first insulating layer 1010, a transistor TR ( [symbol] ), and contact plugs 1008 ( [symbol] [symbol] ).

The semiconductor substrate 1002 may be, for example, a semiconductor wafer or an SOI wafer.

The first insulating layer 1010 may be formed on the top surface of the semiconductor substrate 1002.

The transistors TR may be formed on the upper surface of the semiconductor substrate 1002. The first insulating layer 1010 may cover the transistors TR. The transistors TR may include gate structures 1004 and source/drain structures 1006 on opposite sidewalls of the gate structures 1004. The transistors TR may be, for example, metal-oxide-semiconductor field-effect transistors (MOSFETs), fin field-effect transistors (FinFETs), multi-bridge channel field-effect transistors (MBCFETs), or gate-all-around field-effect transistors (GAAFETs).

The contact plugs 1008 may be formed in the first insulating layer 1010. The contact plugs 1008 may be electrically connected to the transistors TR.

The BEOL structure BE may be formed on the FEOL structure FE. The BEOL structure BE may be electrically connected to the FEOL structure FE. The BEOL structure BE may include second insulating layers 1012, wiring structures 1014, third insulating layers 1016, and a memory array MA.

The second insulating layers 1012 may be formed on the FEOL structure FE. The wiring structures 1014 may be formed in the second insulating layers 1012. The wiring structures 1014 may be electrically connected to the transistors TR of the FEOL structure FE. The wiring structures 1014 may include at least one wire and at least one via.

The memory array MA may be formed on the second insulating layers 1012. The memory array MA may be routed to the transistors TR. The memory array MA may be driven by the transistors TR. The memory array MA may be an array where the memory cells MC, described above with reference to FIGS. 1 through 33, are arranged in a 3D structure. The memory array MA may be embedded in the BEOL structure BE.

The third insulating layers 1016 may be formed on the second insulating layers 1012. The third insulating layers 1016 may cover at least portions of the memory array MA.

Although the embodiments of the present disclosure have been described with reference to the attached drawings, the invention is not limited to these embodiments and may be manufactured in various other forms. It will be understood by those skilled in the art that the disclosure can be embodied in other specific forms without changing the technical spirit or essential features of the invention. Therefore, the embodiments described above should be understood as illustrative and not restrictive in all respects.

What is claimed is:

1. A semiconductor memory device comprising:
gate electrodes spaced apart in a first horizontal direction, extending in a second horizontal direction, and comprising first sidewalls and second sidewalls opposite to the first sidewalls in the first horizontal direction;
first isolation patterns on the first sidewalls and the second sidewalls, spaced apart in the second horizontal direction;
at least one channel layer between adjacent first isolation patterns in the second horizontal direction, contacting at least one of the first sidewalls and at least one of the second sidewalls, the at least one channel layer comprising, in a following order in the first horizontal direction:
a dielectric layer comprising a ferroelectric or antiferroelectric material;
an intermediate electrode;
a gate insulating layer; and
a semiconductor layer; and
source/drain lines extending in a vertical direction between adjacent gate electrodes in the first horizontal direction.

2. The semiconductor memory device of claim 1, wherein the semiconductor layer comprises silicon or an oxide semiconductor.

3. The semiconductor memory device of claim 1, wherein the source/drain lines comprise:
source lines;
drain lines that are spaced apart from the source lines in the second horizontal direction; and
isolation patterns between pairs of adjacent source and drain lines in the second horizontal direction.

4. The semiconductor memory device of claim 3, wherein the isolation patterns are aligned along the first horizontal direction.

5. The semiconductor memory device of claim 3, wherein adjacent isolation patterns are offset in the second horizontal direction.

6. The semiconductor memory device of claim 1, wherein thicknesses of the gate electrodes in the vertical direction is greater than a thickness of the at least one channel layer in the vertical direction.

7. A semiconductor memory device comprising:
insulating layers and gate electrodes alternately stacked in a vertical direction;
source/drain lines spaced apart in a second horizontal direction and extending in the vertical direction on sides of the insulating layers and the gate electrodes in a first horizontal direction;
dielectric layers between the source/drain lines and the gate electrodes, the dielectric layers comprising a ferroelectric or antiferroelectric material;
semiconductor layers between the source/drain lines and the dielectric layers; and
first isolation patterns penetrating at least one of the dielectric layers and at least one of the semiconductor layers and spaced apart in the second horizontal direction.

8. The semiconductor memory device of claim 7, further comprising:
insulating caps between the insulating layers and the source/drain lines, between the insulating layers and the dielectric layers, and between the insulating layers and the semiconductor layers.

9. The semiconductor memory device of claim 8, wherein the insulating caps comprise a same material as the insulating layers.

10. The semiconductor memory device of claim 7, further comprising:
second isolation patterns aligned along the first horizontal direction,
wherein the source/drain lines comprise a source line and a drain line, and
wherein at least one of the second isolation patterns is between the source line and the drain line.

11. The semiconductor memory device of claim 7, wherein the source/drain lines comprise a source line and a drain line, further comprising:
second isolation patterns, wherein adjacent second isolation patterns are offset in the second horizontal direction, and at least one of the second isolation patterns is disposed between the source line and the drain line.

12. The semiconductor memory device of claim 7, wherein the first isolation patterns are aligned along the first horizontal direction.

13. The semiconductor memory device of claim 7, wherein adjacent first isolation patterns are offset in the second horizontal direction.

14. The semiconductor memory device of claim 7, wherein the first isolation patterns are between adjacent source/drain lines in the second horizontal direction.

15. The semiconductor memory device of claim 7, wherein the semiconductor layers comprise silicon or an oxide semiconductor.

16. The semiconductor memory device of claim 7, further comprising:
gate insulating layers between the dielectric layers and the semiconductor layers.

17. The semiconductor memory device of claim 7, further comprising:
intermediate electrodes between the dielectric layers and the semiconductor layers.

18. The semiconductor memory device of claim 17, further comprising:
gate insulating layers between the intermediate electrodes and the semiconductor layers.

19. A semiconductor memory chip comprising:
a front-end-of-line (FEOL) structure comprising a semiconductor substrate and transistors on the semiconductor substrate; and
a back-end-of-line (BEOL) structure on the FEOL structure, comprising a memory array electrically connected to the transistors, wherein the memory array comprises:
insulating layers and gate electrodes alternately stacked in a vertical direction;
source/drain lines spaced apart in a second horizontal direction and extending in the vertical direction on sides of the insulating layers and the gate electrodes in a first horizontal direction;
at least one channel layer between the source/drain lines and the gate electrodes, the at least one channel layer comprising:
a dielectric layer comprising a ferroelectric or antiferroelectric material;
a gate dielectric layer; and
a semiconductor layer; and
first isolation patterns extending in the vertical direction, penetrating at least a portion of the at least one channel layer, and disposed between adjacent source/drain lines in the second horizontal direction.

20. The semiconductor memory chip of claim 19, further comprising:
insulating caps between the insulating layers and the source/drain lines, and between the insulating layers and the at least one channel layer, wherein the insulating caps comprise a same material as the insulating layers.
